(19) United States
(12) Patent Application Publication
(10) Pub. No.: US 2026/0282706 A1
(43) Pub. Date: Sep. 17, 2026

(54) DISPLAY DEVICE, METHOD OF MANUFACTURING THE SAME AND ELECTRONIC DEVICE INCLUDING THE SAME

(71) Applicant: SAMSUNG DISPLAY CO., LTD., YONGIN-SI (KR)

(72) Inventors: Woo Suk JANG, Yongin-si (KR); Yong Hak KIM, Yongin-si (KR); Jong Gouk LEE, Yongin-si (KR)

(21) Appl. No.: 19/548,317

(22) Filed: Feb. 24, 2026

(30) Foreign Application Priority Data
Mar. 11, 2025 (KR) 10-2025-0031098

(51) Int. Cl. H10K 59/80; H10K 59/12; H10K 102/00

(52) U.S. Cl. CPC H10K 59/8722; H10K 59/1201; H10K 2102/311

(57) ABSTRACT

A display device includes a display panel having a folding area and a non-folding area, an upper structure disposed on the display panel in a thickness direction of the display device and including an upper cover, a lower structure disposed under the display panel and including a lower support plate that includes lattice bars in an area overlapping the folding area, and a first sealing material disposed on a portion of a side surface of the display panel corresponding to the folding area. The first sealing material includes a first sub-sealing material disposed on the portion of the side surface of the display panel corresponding to the folding area, and a second sub-sealing material disposed on an upper surface of the first sub-sealing material to partially overlap the first sub-sealing material in a direction perpendicular to the thickness direction.

### CROSS-REFERENCE TO RELATED APPLICATION(S)

This application claims priority under 35 U.S.C. § 119 to and benefits from Korean Patent Application No. 10-2025-0031098 filed on Mar. 11, 2025 in the Korean Intellectual Property Office (KIPO), the entire contents of which is herein incorporated by reference.

### TECHNICAL FIELD

Embodiments of the disclosure relate to a display device including a display panel and functional layers, a method of manufacturing the same and an electronic device including the same.

### DISCUSSION OF THE RELATED ART

In a display device such as an organic light emitting diode (OLED) display device or a liquid crystal display (LCD) device, a display substrate including thin film transistors (TFTs) and various wirings may be included. A display structure including electrodes and emission layers may be formed on the display substrate to provide a display panel.

A window cover may be attached to the display panel, and lower structures such as a supporting plate and a cover panel may be disposed under the display panel. For example, the display device may have a folding area, and a sealing material may be formed around the folding area. However, mechanical damages to the display panel may occur due to external impact and folding/bending applied to the display device. Further, flexibility may be lowered by the sealing material.

### SUMMARY

According to embodiments of the disclosure, there is provided a display device having improved structural and mechanical reliability.

According to embodiments of the disclosure, there is provided a method of manufacturing a display device having improved structural and mechanical reliability.

According to embodiments of the disclosure, there is provided an electronic device having improved structural and mechanical reliability.

According to an embodiment, a display device includes a display panel having a folding area and a non-folding area. The display device further may include an upper structure disposed on the display panel in a thickness direction of the display device, the upper structure may include an upper cover. The display device may further include a lower structure disposed under the display panel in the thickness direction of the display device, the lower structure may include a lower support plate including lattice bars in an area overlapping the folding area. The display device may further include a first sealing material disposed on a portion of a side surface of the display panel corresponding to the folding area. The first sealing material may include a first sub-sealing material disposed on the portion of the side surface of the display panel corresponding to the folding area, and a second sub-sealing material may be disposed on an upper surface of the first sub-sealing material to partially overlap the first sub-sealing material in a direction perpendicular to the thickness direction.

In some embodiments, the first sealing material may not cover a side surface of the lower support plate.

In some embodiments, a width of the second sub-sealing material in the direction perpendicular to the thickness direction may be less than a width of the first sub-sealing material in the direction perpendicular to the thickness direction.

In some embodiments, the second sub-sealing material may contact a side surface of the upper structure and may not contact the side surface of the display panel.

In some embodiments, the first sub-sealing material may contact an entirely of a portion of the side surface of the display panel corresponding to the folding area.

In some embodiments, the first sealing material may further include a third sub-sealing material contacting an upper surface of the second sub-sealing material to partially overlap the second sub-sealing material in the direction perpendicular to the thickness direction. The third sub-sealing material and the first sub-sealing material may be spaced apart from each other in the thickness direction.

In some embodiments, a width of the first sub-sealing material in the direction perpendicular to the thickness direction may be greater than a width of the second sub-sealing material in the direction perpendicular to the thickness direction, and the width of the second sub-sealing material in the direction perpendicular to the thickness direction may be greater than a width of the third sub-sealing material in the direction perpendicular to the thickness direction.

In some embodiments, the second sub-sealing material may partially overlap upper surfaces of the first sub-sealing material and the third sub-sealing material in the direction perpendicular to the thickness direction at locations between the first sub-sealing material and the third sub-sealing material.

In some embodiments, a width of the second sub-sealing material in the direction perpendicular to the thickness direction may be less than each of a width of the first sub-sealing material in the direction perpendicular to the thickness direction and a width of the third sub-sealing material in the direction perpendicular to the thickness direction.

In some embodiments, the second sub-sealing material may have a width in the direction perpendicular to the thickness direction that decreases in the thickness direction from the display device to the upper structure.

In some embodiments, a virtual straight line connecting a lowermost point and an uppermost point of the second sub-sealing material, and another virtual straight line connecting the lowermost point of the second sub-sealing material and a point where the second sub-sealing material, the first sub-sealing material and the side surface of the display device meet each other may form an acute intersection angle.

In some embodiments, the display device may further include a second sealing material overlapping portions of the side surface of the display panel corresponding to the non-folding area in the direction perpendicular to the thickness direction.

In some embodiments, the second sealing material may include the first sub-sealing material and the second sub-sealing material.

In some embodiments, the second sealing material may be a single, uninterrupted sealing member.

In some embodiments, the second sealing material may overlap a side surface of the lower support plate in the direction perpendicular to the thickness direction.

In a method of manufacturing a display device according to some embodiments, the method may include preparing a display device including a lower support plate, a display panel and an upper cover sequentially stacked on each other. The method may also include forming a first preliminary sealing material by coating a resin composition on a portion of a side surface of the display panel corresponding to a folding area of the display device. The method may also include curing the first preliminary sealing material to form a first sub-sealing material, coating a second preliminary sealing material by coating the resin composition to partially overlap an upper surface of the first sub-sealing material in a direction perpendicular to a thickness direction of the display device, and curing the second preliminary sealing material to form a second sub-sealing material.

In some embodiments, a coating amount of the resin composition for forming the second preliminary sealing material may be less than a coating amount of the resin composition for forming the first preliminary sealing material.

In some embodiments, the first preliminary sealing material may not overlap in the direction perpendicular to the thickness direction a portion of a side surface of the lower support plate corresponding to the folding area.

An electronic device according to some embodiments may include a display device, a memory, and a processor executing data included in the memory to control an operation of the display device. The display device may include a display panel having a folding area and a non-folding area, an upper structure disposed on the display panel in a thickness direction of the display device, the upper structure may include an upper cover, a lower structure may be disposed under the display panel in the thickness direction of the display device, the lower structure may include a lower support plate including lattice bars in an area overlapping the folding area. The electronic device may also include a first sealing material disposed on a portion of a side surface of the display panel corresponding to the folding area. The first sealing material may include a first sub-sealing material disposed on the portion of the side surface of the display panel corresponding to the folding area, and a second sub-sealing material may be disposed on an upper surface of the first sub-sealing material to partially overlap the first sub-sealing material in a direction perpendicular to the thickness direction.

In some embodiments, the electronic device may include virtual reality or augmented reality glasses, a smartphone, a tablet, a laptop, a TV, a desk, smart glasses, a head-mounted display, a smart watch, or a vehicle display.

According to embodiments of the disclosure, a display device may include a sealing material that includes a first sub-sealing material and a second sub-sealing material disposed on a portion of a side surface of the display device corresponding to a folding area of a display device to overlap each other in a direction perpendicular to a thickness direction of the display device. The sealing material may be divided to prevent a sealing resin from penetrating into and aggregating on a portion of a lower support plate corresponding to the folding area. An overall size of the sealing material may be reduced so that a deco area or a bezel area of the display device may be reduced.

### BRIEF DESCRIPTION OF THE DRAWINGS

Illustrative, non-limiting embodiments will be more clearly understood from the following detailed description in conjunction with the accompanying drawings.

FIG. 1 is an exploded perspective view illustrating a display device or an electronic device according to embodiments.

FIGS. 2 and 3 are a schematic plan view and a schematic cross-sectional view, respectively, illustrating a display panel according to embodiments.

FIGS. 4 and 5 are a schematic plan view and a schematic cross-sectional view, respectively, illustrating a display device according to embodiments.

FIG. 6 is a schematic cross-sectional view illustrating a side portion of a folding area of a display device according to embodiments.

FIG. 7 is a schematic cross-sectional view illustrating a side portion of a folding area of a display device according to embodiments.

FIG. 8 is a schematic cross-sectional view illustrating a side portion of a folding area of a display device according to embodiments.

FIG. 9 is a schematic cross-sectional view illustrating a side portion of a folding area of a display device according to embodiments.

FIG. 10 is a schematic cross-sectional view illustrating a side portion of a folding area of a display device according to embodiments.

FIG. 11 is a schematic cross-sectional view illustrating a side portion of a folding area of a display device according to embodiments.

FIG. 12 is a schematic cross-sectional view illustrating a side portion of a non-folding area of a display device according to embodiments.

FIG. 13 is a schematic cross-sectional view illustrating a side portion of a non-folding area of a display device according to embodiments.

FIG. 14 is a block diagram of an electronic device according to an embodiment.

FIG. 15 is a schematic diagram of electronic devices according to embodiments.

### DETAILED DESCRIPTION OF THE EMBODIMENTS

Hereinafter, embodiments of the disclosure will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the disclosure. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown.

The terms "on", "connected", "coupled," etc., used herein refers to a direct placement/connection/combination, and also refers to a case where another element is disposed between two different elements.

The terms such as "first", "second", "below", "lower", "upper", "above," etc., are used in a relative sense to distinguish different elements or positions, and do not specify an absolute position or an absolute order.

The term "adhesive" used herein encompasses both a pressure-sensitive adhesive layer or material, and a bonding layer or material.

In the disclosure, terms "top (or upper)" and "bottom (or lower)" may be classified based on a direction from a frame FR to a window structure WS.

According to embodiments of the disclosure, there is provided a display device, an electronic device including the display device, and a method of manufacturing the display device, in which sealing material is disposed on a portion of side surfaces of the display device corresponding to a folding area. The sealing material may include multiple sealing layers. By applying the sealing layers sequentially, penetration and aggregation of the sealing material into openings of a lower support plate of a lower structure may be prevented, and a size in a plan view of an area occupied by the sealing material and the bezel can be reduced.

Several embodiments are disclosed. The embodiments apply a first preliminary sealing material that overlaps a portion of the side surface of the display device that corresponds to the display panel DP and that corresponds to the folding (or bezel) area. This first preliminary sealing material is then cured to form a first sub-sealing material. A second preliminary sealing material that overlaps a portion of an exposed surface of the first sub-sealing material and a portion of the side surface of the display device that corresponds to the upper structure corresponding to the folding area is applied and then allowed to cure to form a second sub-sealing material. A smaller amount of the second preliminary sealing material is applied compared to the first preliminary sealing material. In some embodiments, a third sub-sealing layer may also be formed. The first sub-sealing material serves as a dam to prevent the second preliminary sealing material from flowing onto the lower structure and into openings in the lower support plate. As a result, sealing material does not aggregate in the openings of the lower support plate of the lower structure, and an area in a plan view occupied by the sealing material and the bezel can be reduced while layers of the display device are protected from infiltration of moisture and oxygen.

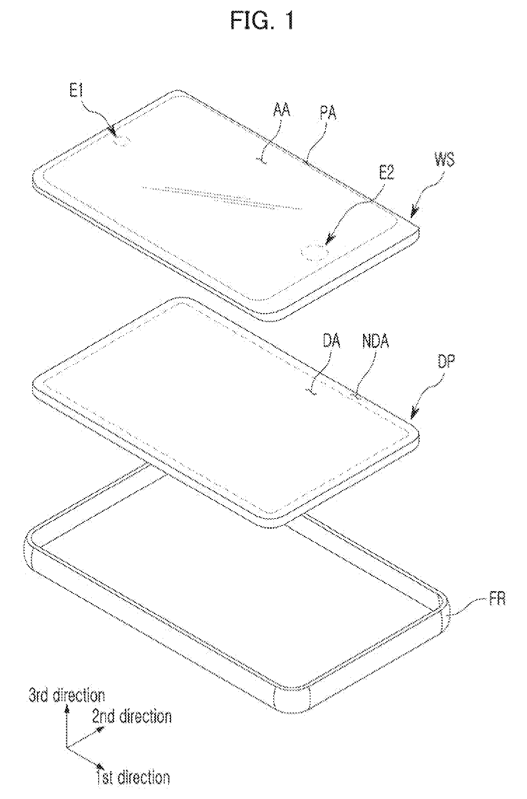

FIG. 1 is an exploded perspective view illustrating a display device or an electronic device according to embodiments.

In FIG. 1, a first direction and a second direction may refer to two directions parallel to a display surface of a display device DD or a display panel DP, and perpendicular to each other. For example, the first direction may correspond to a length direction or an X-direction (a row direction) of the display device DD or the display panel DP, and the second direction may correspond to a width direction or a Y-direction (a column direction) of the display device DD or the display panel DP.

A third direction may be perpendicular to the first direction and the second direction. The third direction may correspond to a Z-direction (a thickness direction) of the display device DD or the display panel DP.

The definitions of the directions described above may be equally applied to the accompanying drawings.

Referring to FIG. 1, the electronic device may be implemented in the form of a mobile phone (smart phone), a tablet, a PC, or the like, including a display device.

The electronic device may include a window structure WS, the display panel DP, and a frame FR. The frame FR, the display panel DP, and the window structure WS may be sequentially stacked on each other in the third direction.

The display device may include a liquid crystal display (LCD) device, an organic light-emitting diode (OLED) display device, a quantum dot light-emitting diode (QLED) display device, or the like. According to embodiments, the display device DD may be an OLED display device including an organic emission layer.

The window structure WS may provide an external display surface recognized by a user, such as a viewing surface of an electronic device (e.g., a mobile phone) and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area or a black matrix area of the electronic device.

The display panel DP may include a display area DA and a non-display area NDA. The display area DA of the display panel DP may substantially correspond to or overlap the active area AA of the window structure WS.

The non-display area NDA of the display panel DP may substantially correspond to or overlap the peripheral area PA of the window structure WS. In some embodiments, the peripheral area PA of the window structure WS may include a margin area that does not overlap the display panel DP.

In some embodiments, functional device areas E1 and E2 may be included in the active area AA of the window structure WS. For example, a first functional device area E1 may be included at an end portion of the active area AA and may be implemented to serve as a camera hole. The second functional device area E2 may serve as a fingerprint sensing area.

For example, a sensor structure for a touch sensing or a fingerprint sensing may be disposed in the display panel DP or between the window structure WS and the display panel DP.

The frame FR may serve as a frame structure or a housing of the electronic device. A cover panel may be disposed between the frame FR and the display panel DP. The cover panel may include an elastic body for absorbing shock of the display panel DP.

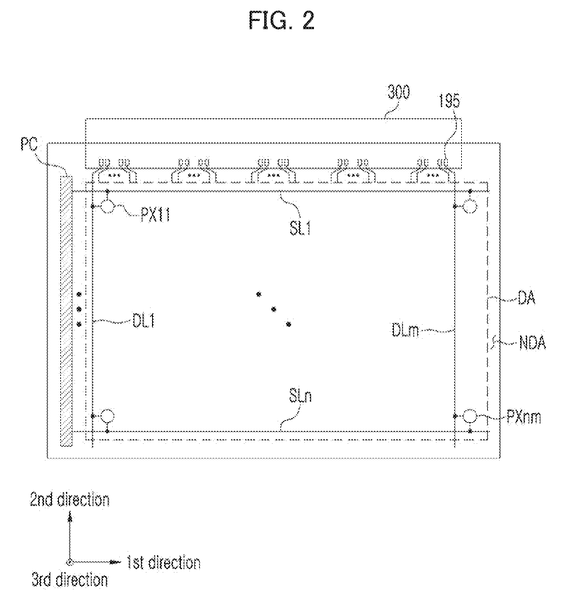

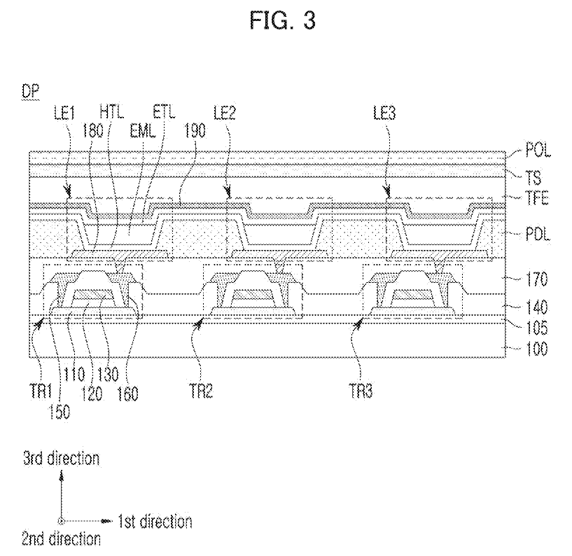

FIGS. 2 and 3 are a schematic plan view and a cross-sectional view, respectively, illustrating a display panel according to embodiments.

Referring to FIG. 2, multiple pixels PX11 to PXnm may be arranged in a display area DA of the display panel DP.

According to embodiments, a pixel circuit including scan lines (or gate lines SL1 to SLn) forming first to nth rows and data lines DL1 to DLm forming first to mth columns may be arranged on a base substrate 100 of the display device. Each of the pixels PX11 to PXnm may be connected to a scan line of a corresponding row among multiple scan lines SL1 to SLn and a data line of a corresponding column among multiple data lines DL1 to DLm.

Each of the pixels PX11 to PXnm may further include a pixel driving circuit including a transistor and a light-emitting device as described below. Although not illustrated in detail in FIG. 2, the pixel circuit may further include wirings such as a power line, a ground line, or the like.

In FIG. 2, data lines DL1 to DLm extend in the second direction, and scan lines SL1 to SLn may extend in the first direction, but the disclosure is not necessarily limited to the construction illustrated in FIG. 2.

A peripheral circuit PC may be disposed in the non-display area NDA corresponding to a peripheral area with respect to the display area DA. For example, the peripheral circuit PC may include a gate driving circuit. The gate driving circuit may be integrated into the display device by an oxide semiconductor gate (OSG) driver circuit process, an amorphous silicon gate (ASG) driver circuit process, or a polysilicon gate (PSG) driver circuit process.

The display device may further include a printed circuit board 300. Pads 195 of the pixel circuit may be assembled on a side portion of the non-display area NDA. The printed circuit board 300 may be electrically connected to the pixel circuit through the pads 195. For example, the printed circuit board 300 may be electrically connected to the pads 195 by a thermocompression technique using a conductive intermediate structure such as an anisotropic conductive film (ACF).

Although FIG. 2 illustrates that the printed circuit board 300 and the pads 195 are disposed at an end of the display panel DP in the second direction, the printed circuit board 300 and the pads 195 may be disposed at an end portion of the display panel DP in the first direction.

An integrated circuit (IC) such as a data driving circuit may be disposed on the printed circuit board 300. In some embodiments, an integrated circuit (IC) chip in the form of a chip-on-film (COF) may be mounted on the printed circuit board 300.

Referring to FIG. 3, the display panel DP may include a base substrate 100, a circuit layer disposed on the base substrate 100, and a light-emitting device disposed on the circuit layer.

The base substrate 100 may serve as a back-plane substrate of a display device. A glass substrate or a plastic substrate may be used as the base substrate 100.

In some embodiments, the base substrate 100 may include a polymer material having transparency and flexibility. In this case, the base substrate 100 may be used in a transparent flexible display device. For example, the base substrate 100 may include a polymer material such as polyimide, polysiloxane, an epoxy resin, an acrylic resin, polyester, the like, or a combination thereof. In an embodiment, the base substrate 100 may include polyimide.

The circuit layer may include transistors TR1, TR2 and TR3. The circuit layer may also include wiring layers and insulation layers forming a thin film transistor array TFT-Array.

The circuit layer may further include a buffer layer 105 formed on a top surface of the base substrate 100. Moisture penetrating through the base substrate 100 may be blocked by the buffer layer 105, and diffusion of impurities between the base substrate 100 and structures formed on the base substrate 100 may also be blocked by the buffer layer 105.

The buffer layer 105 may include, e.g., an inorganic insulating material such as silicon oxide, silicon nitride, or silicon oxynitride. These may be used alone or in a combination thereof. In some embodiments, the buffer layer 105 may have a stacked structure including a silicon oxide layer and a silicon nitride layer.

The buffer layer 105 may be formed by a deposition process such as a chemical vapor deposition (CVD) process, a sputtering process, an atomic layer deposition (ALD) process, or the like, to include the inorganic insulating material described above.

The transistors TR1, TR2, and TR3 may be disposed on the buffer layer 105. The first transistor TR1, the second transistor TR2, and the third transistor TR3 may be electrically connected to a first light-emitting device LE1, a second light-emitting device LE2, and a third light-emitting device LE3, respectively.

Each of the transistors TR1, TR2 and TR3 may include an active layer 110, a gate insulating layer 120, and a gate electrode 130.

The active layer 110 may be disposed on the buffer layer 105, and may be patterned by, e.g., a photo-lithography process to be repeatedly/regularly arranged at each pixel. The active layer 110 may include a silicon compound such as polysilicon or amorphous silicon. A p-type dopant or an n-type dopant may be doped in a partial region of the active layer 110 so that the active layer 110 may include a source region, a drain region, and a channel region.

The active layer 110 may include an oxide semiconductor such as indium gallium zinc oxide (IGZO), zinc tin oxide (ZTO), indium tin zinc oxide (ITZO), or a combination thereof.

The gate insulating layer 120 may be formed on the active layer 110, and the gate electrode 130 may be disposed on the gate insulating layer 120. As illustrated in FIG. 3, the gate insulating layer 120 may be formed in a pattern shape partially covering each active layer 110. For example, the gate insulating layer 120 may extend continuously throughout multiple pixels or light-emitting regions, and may be provided commonly in the first to third transistors TR1, TR2 and TR3.

The gate electrode 130 may overlap the channel region of the active layer 110 in a vertical direction. A scan signal may be transmitted from the scan line through the gate electrode 130.

The gate insulating layer 120 may be formed by the above-mentioned deposition process to include an inorganic insulating material such as silicon oxide, silicon nitride, silicon oxynitride, the like, or a combination thereof. In some embodiments, the gate insulating layer 120 having the pattern shape as illustrated in FIG. 3 may be formed by a photo-lithography process using the gate electrode 130 as an etching mask.

In some embodiments, the gate electrode 130 and the gate insulating layer 120 may be used as ion implantation masks to form the source region and the drain region in the active layer 110.

An insulating interlayer 140 covering the gate insulating layer 120 and the gate electrode 130 may be formed on the active layer 110. Connection electrodes 150 and 160, which are in contact with or electrically connected to the active layer 110, may be formed on the insulating interlayer 140.

The insulating interlayer 140 may be formed through the above-described deposition process to include an inorganic insulating material such as silicon oxide, silicon nitride, silicon oxynitride, the like, or a combination thereof. The insulating interlayer 140 may be formed in a single-layered structure or a multi-layered structure including different materials.

In some embodiments, when the active layer 110 includes an oxide semiconductor, hydrogen (H) contained in the insulating interlayer 140 may be diffused or transferred to vacancy sites induced in the active layer 110 when forming the gate insulating layer 120. Accordingly, a carrier concentration may be increased by hydrogen, so that the source region and the drain region having increased conductivity may be formed at the side portions of the active layer 110.

The connection electrodes 150 and 160 may extend through the insulating interlayer 140 to be connected to the active layer 110. When the gate insulating layer 120 is continuously formed commonly in multiple pixel regions, the connection electrodes 150 and 160 may also extend through the gate insulating layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially etching the insulating interlayer 140. For example, the contact holes exposing the source region and the drain region, respectively, may be formed. A metal layer filling the contact holes may be formed on the insulating interlayer 140, and then may be partially etched to form the source electrode 150 and the drain electrode 160. For example, the source electrode 150 may be connected to the above-described data line.

The gate electrode 130 and the connection electrodes 150 and 160 may include a metal such as Ag, Mg, Al, W, Cu, Ni, Cr, Mo, Ti, Pt, Ta, Nd, Sc, or the like, an alloy thereof, or a nitride thereof. The gate electrode 130 and the connection electrodes 150 and 160 may be formed by the above-described deposition process and the photo-lithography process.

A planarization layer 170 covering the connection electrodes 150 and 160 may be formed on the insulating interlayer 140. The planarization layer 170 may accommodate a via structure electrically connecting a pixel electrode 180 and the drain electrode 160.

In some embodiments, the planarization layer 170 may include an organic material such as polyimide, an epoxy resin, an acrylic resin, polyester, a siloxane resin, benzocyclobutene (BCB), the like, or a combination thereof. The planarization layer 170 may be formed by the above-described deposition process or a spin coating process.

The pixel electrode 180 may be formed in each pixel to be electrically connected to the transistors TR1, TR2 and TR3. The pixel electrode 180 may be formed on the planarization layer 170 to be electrically connected to the drain electrode 160.

For example, the planarization layer 170 may be partially etched to form a via hole exposing a top of the drain electrode 160. A conductive layer including a metal or a transparent conductive oxide and filling the via hole may be formed on a top surface of the planarization layer 170, and the conductive layer may be etched to form the pixel electrode 180.

The pixel electrode 180 may be provided as an anode, and may include a high work function conductive material capable of promoting hole injection. The pixel electrode 180 may be formed as a transmissive electrode. The pixel electrode 180 may include a transparent conductive oxide such as indium tin oxide (ITO), indium zinc oxide (IZO), zinc oxide (ZnO), indium tin zinc oxide (ITZO), the like, or a combination thereof.

The pixel electrode 180 may be formed as a translucent electrode or a reflective electrode. The pixel electrode 180 may include a metal selected from Ag, Mg, Cu, Al, Pt, Pd, Au, Ni, Nd, Ir, Cr, Li, Ca, Mo, Ti, W, In, Sn and Zn, an alloy, a compound (e.g., LiF) including at least one therefrom, or a combination thereof.

The pixel electrode 180 may have a single-layered structure or a multi-layered structure. For example, the pixel electrode 180 may have a triple-layered structure such as ITO/Ag/ITO or ITO/Al/ITO.

A pixel defining layer PDL, a light-emitting portion, and a counter electrode 190 may be disposed on the above-described circuit layer. The light-emitting devices LE1, LE2, and LE3 may be defined by the pixel electrode 180, the light-emitting portion, and the counter electrode 190.

The pixel defining layer PDL may be formed on the planarization layer 170 to expose a top surface of the pixel electrode 180. The light-emitting region may be defined by a sidewall of the pixel defining layer PDL. A red light-emitting region, a green light-emitting region, and a blue light-emitting region may be separated and defined by the pixel defining layer PDL, and the first light-emitting device LE1, the second light-emitting device LE2, and the third light-emitting device LE3 may correspond to a blue light-emitting device, a green light-emitting device, and a red light-emitting device, respectively.

In some embodiments, all of the light-emitting devices LE1, LE2 and LE3 may be white light emitting devices or blue light emitting devices.

The light-emitting portion may be disposed in each light-emitting region formed by the pixel defining layer PDL. According to embodiments, the light-emitting portion may include an emission layer EML including an organic light-emitting material. The emission layer EML may include an organic light-emitting material. For example, the emission layer EML includes a fluorescent host and/or a host for a phosphorescent device, and may further include a fluorescent dopant, a phosphorescent dopant, and/or a thermally activated delayed fluorescent (TADF) dopant.

For example, the light-emitting portion may be formed by a process such as a thermal deposition, a vapor deposition, a vacuum deposition, a spin coating, an inkjet printing, a laser printing, a casting, a laser thermal transfer, or the like.

The counter electrode 190 may be disposed on a top surface of the pixel defining layer PDL and the-light emitting portions. The counter electrode 190 may be a common electrode that is continuously provided commonly in multiple the light-emitting regions or pixels.

The counter electrode 190 may be provided as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in s combination of two or more therefrom.

The counter electrode 190 may be formed as a transmissive electrode, a translucent electrode, or a reflective electrode. The counter electrode 190 may have a single-layered structure or a multi-layered structure.

The light-emitting portion may further include a hole transport layer HTL and an electron transport layer ETL. According to embodiments, the hole transport layer HTL, the emission layer EML, the electron transport layer ETL and the counter electrode 190 may be sequentially stacked on each other from the top surface of the pixel electrode 180.

For example, the hole transport layer HTL may include a hole transporting material such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or the like.

In some embodiments, a hole injection layer may be further formed between the pixel electrode 180 and the hole transport layer HTL. An electron injection layer may be further formed between the counter electrode 190 and the electron transport layer ETL.

In some embodiments, the emission layer EML may be patterned to be disposed in the light-emitting region defined by the pixel defining layer PDL. Accordingly, the light-emitting portions in the form of an island may be spaced apart from each other at each of multiple pixels.

In some embodiments, the layers included in the above-described light-emitting portion may continuously and commonly extend over the pixels and the top surface of the pixel defining layer PDL. For example, the hole transport layer HTL and the electron transport layer ETL may be included as a common layer for the light-emitting devices LE1, LE2, and LE3.

In some embodiments, an encapsulation layer TFE covering the light-emitting devices LE1, LE2 and LE3 may be disposed on the display panel DP. In an embodiment, the encapsulation layer TFE may be included as an element of the display panel DP.

The encapsulation layer TFE may be disposed on the pixel defining layer PDL and the light-emitting devices LE1, LE2 and LE3 to protect the light-emitting devices LE1, LE2 and LE3 from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer and a second inorganic layer.

In some embodiments, a color control layer overlapping the light-emitting portion or the emission layer EML may be disposed on the encapsulation layer TFE. The color control layer may include a color conversion layer including quantum dots and/or a color filter.

In some embodiments, a touch sensor layer TS may be disposed on the encapsulation layer TFE. The touch sensor layer TS may include a sensor substrate layer and sensor electrodes arranged on the sensor substrate layer. The touch sensor layer TS may be directly disposed on the encapsulation layer TFE as an on-cell type sensor. An adhesive layer may be disposed between the touch sensor layer TS and the encapsulation layer TFE.

In some embodiments, a polarizing plate POL may be disposed on the touch sensor layer TS. An adhesive layer may be disposed between the touch sensor layer TS and the polarizing plate POL.

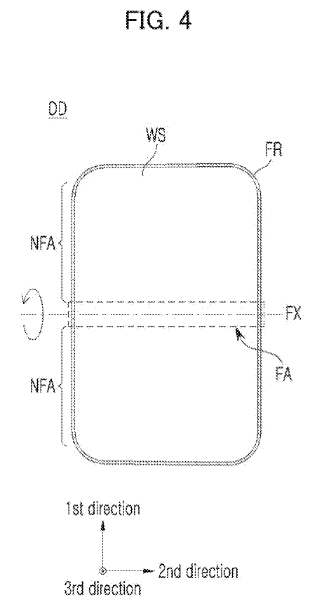

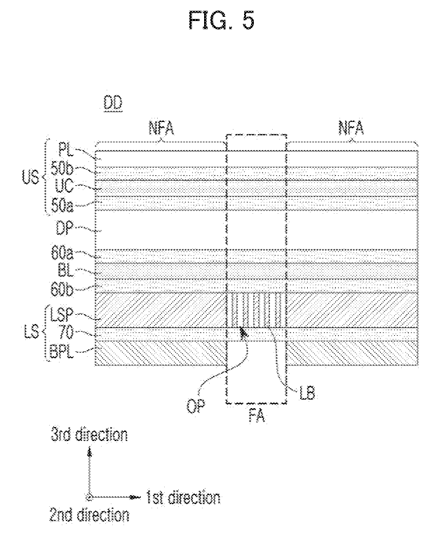

FIGS. 4 and 5 are a schematic plan view and a schematic cross-sectional view, respectively, illustrating a display device according to embodiments. For example, FIG. 4 is a schematic plan view illustrating a front face portion of the display device DD. FIG. 5 is a cross-sectional view of a folding area and a stacked structure around the folding area (a portion of the non-folding area) taken in the first direction in the third direction.

For convenience of descriptions, illustration of a sealing material is omitted in FIG. 5.

Referring to FIG. 4, the front face portion of the display device DD may be provided by the window structure WS of the display device DD. The frame FR may be coupled to an outer periphery of the display device DD to fix together the display panel DP, the window structure WS, an upper structure US, and a lower structure LS.

The display device DD may include a folding area FA and a non-folding area NFA. Accordingly, the display panel DP may include a folding area FA and a non-folding area NFA, and the folding area FA and the non-folding area NFA of the display panel DP may also substantially correspond to the folding area FA and the non-folding area NFA of the display device DD, respectively.

The folding area FA may be included in a central area of the display device DD. According to embodiments, the folding area FA may have a folding axis FX extending in the second direction (e.g., a width direction of the display device DD). The display device DD may be folded around the folding axis FX.

According to embodiments, the non-folding area NFA may be included at each side portion of the folding area FA in the first direction.

Referring to FIG. 5, the display device DD may include the upper structure US disposed on a top surface of the display panel DP and a lower structure LS disposed under a bottom surface of the display panel DP.

The upper structure US may include an upper cover UC. The upper cover UC may include glass (e.g., ultra-thin glass UTG) or a transparent plastic film.

The upper structure US may further include a protective layer PL disposed on the upper cover UC. The protective layer PL may include, e.g., a transparent resin film having impact resistance, such as a hard coating film.

In some embodiments, the upper cover UC may be attached onto the display panel DP by a first upper adhesive layer 50a. The protective layer PL may be attached onto the upper cover UC by a second upper adhesive layer 50b.

The lower structure LS may include a lower support plate LSP. The lower support plate LSP may include a resin plate such as polyurethane, a ceramic plate, or an organic-inorganic composite plate. In some embodiments, the lower support plate LSP may include a reinforced plastic including inorganic fibers such as carbon fibers. An overall rigidity of the display device DD may be maintained by the lower support plate LSP.

In example embodiments, openings OP may be formed in a portion of the lower support plate LSP corresponding to the folding area FA, thereby enhancing flexibility in the folding area FA. The openings OP may have a hole shape or a trench shape penetrating the lower support plate LSP. The openings OP may refer to a recess-shaped thin film portion of the lower support plate LSP.

The lower support plate LSP may include a lattice bar LB formed in the folding area FA. The lattice bar LB may extend in a direction parallel to the folding axis FX (e.g., the second direction). Multiple the lattice bars LB may be arranged in the first direction in the folding area FA. The openings OP may each be formed between adjacent lattice bars LB, respectively.

In some embodiments, a bottom plate BPL may be additionally disposed under the lower support plate LSP.

For example, the bottom plate BPL may include a metal plate such as an SUS (i.e., “steel use stainless”) plate. In some embodiments, the bottom plate BPL may be provided as a fixing plate of a main board, a battery, or the like. In an embodiment, the bottom plate BPL may function as a heat dissipation sheet.

The bottom plate BPL may be included in the non-folding area NFA. Accordingly, degradation of flexibility in the folding area FA due to the bottom plate BPL may be prevented. In some embodiments, the bottom plate BPL may not overlap the lattice bar LB in the third direction. In some embodiments, the bottom plate BPL may be substantially excluded from the folding area FA.

A lower adhesive layer 70 may be included between the lower support plate LSP and the bottom plate BPL. Accordingly, the lower support plate LSP and the bottom plate BPL may be combined with each other.

In some embodiments, a barrier layer BL may be further included between the display panel DP and the lower structure LS. The barrier layer BL may be included as a damping film for mitigating or absorbing impact to the display device DD.

For example, the barrier layer BL may include a polyester resin such as polyethylene terephthalate, polyethylene isophthalate, polyethylene naphthalate, polybutylene terephthalate, or the like; a cellulose resin such as diacetylcellulose, triacetylcellulose, or the like; an acrylic resin such as polycarbonate resin, polymethyl(meth)acrylate, polyethyl(meth)acrylate, or the like; a styrene resin; a polyolefin resin such as polyethylene, polypropylene, cycloolefin resin, or the like; an amide resin; a vinyl alcohol resin; a vinylidene chloride resin; a vinylbutyral resin; an epoxy resin; an urethane resin; a silicone resin; a rubber or elastomer-based resin, or the like. These may be used alone or in a combination of two or more therefrom.

In some embodiments, the barrier layer BL may be attached to a bottom surface of the display panel DP by the first adhesive layer 60a. A second adhesive layer 60b may be included between the barrier layer BL and the lower structure LS.

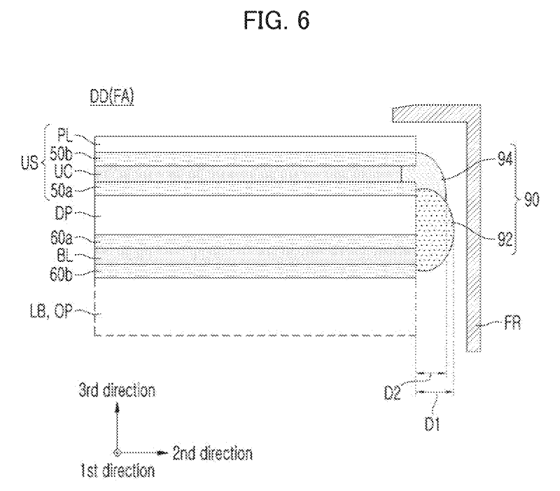

FIG. 6 is a schematic cross-sectional view illustrating a side portion of a folding area of a display device according to embodiments. In FIG. 6 and the following drawings, a method of manufacturing a display device including a formation of a sealing material may also be described.

Hereinafter, the "a side surface of a display device" may refer to a side surface of a stacked structure including the display panel DP, the upper structure US, and the lower structure LS and excluding the frame FR.

Referring to FIG. 6, a first sealing material 90 may be formed on a side surface of the display device DD in the folding area FA. The first sealing material 90 may be formed on each of both side surfaces of the display device DD in the folding area FA.

The first sealing material 90 may include a resin material such as an acrylic resin, a silicone resin, an epoxy resin, a urethane resin, an imide resin, the like, or a combination thereof.

According to embodiments of the disclosure, the first sealing material 90 may include a first sub-sealing material 92 and a second sub-sealing material 94. The first sub-sealing material 92 may be formed on the side surface of the display device DD, the second sub-sealing material 94 may be formed on an upper surface of the first sub-sealing material 92 and may be formed on the side surface of the display device DD. The upper surface of the first sub-sealing material 92 may be all peripheral or exterior surfaces of the first sub-sealing material 92 not in contact with the side surface of the display device DD. The side surface of the display device DD may face a direction perpendicular (i.e., in the second direction) to a thickness direction of the display device DD.

The first sub-sealing material 92 may be in contact with the side surface of the display device DD, and the second sub-sealing material 94 may be in contact with the upper surface of the first sub-sealing material 92 and a side surface of the display device DD.

According to embodiments, the first sub-sealing material 92 may cover (or overlap) a side surface of the display panel DP. In some embodiments, the first sub-sealing material 92 may cover an entirety of a portion of a side surface of the display panel DP corresponding to the folding area FA. In an embodiment, the first sub-sealing material 92 may also cover a side surface of the barrier layer BL disposed under the display panel DP in the thickness direction (or third direction) of the display device DD.

The first sub-sealing material 92 may not be formed on a side surface of the lower support plate LSP including the lattice bar LB. Accordingly, the first sub-sealing material 92 may not exist in the opening OP between the lattice bars LB.

In some embodiments, the first sub-sealing material 92 may entirely cover a side surface of the first adhesive layer 60a in the folding area FA and may partially cover a side surface of the second adhesive layer 60b. The first sub-sealing material 92 may at least partially cover a portion of a side surface of the first upper adhesive layer 50a corresponding to the folding area FA.

The second sub-sealing material 94 may partially cover the upper surface of the first sub-sealing material 92 in a direction perpendicular to a thickness direction of the display device DD (i.e., in the second direction). Accordingly, the first sub-sealing material 92 and the second sub-sealing material 94 may have a partially overlapping stacked structure in which adjacent end portions overlap each other in the direction perpendicular to the thickness direction of the display device DD (i.e., in the second direction).

The second sub-sealing material 94 may at least partially cover a portion of a side surface of the upper structure US corresponding to the folding area FA. In some embodiments, the second sub-sealing material 94 may entirely cover the portion of the side surface of the upper cover UC corresponding to the folding area FA. In an embodiment, the second sub-sealing material 94 may partially cover a portion of a side surface of the protective layer PL corresponding to the folding area FA.

The second sub-sealing material 94 may cover a remaining portion of a portion of the side surface of the first upper adhesive layer 50a corresponding to the folding area FA, and may at least partially cover the side surface of the second upper adhesive layer 50b in the direction perpendicular to the thickness direction of the display device DD (i.e., in the second direction).

According to embodiments, each of the first sub-sealing material 92 and the second sub-sealing material 94 may have an embossed pattern shape protruding from the side surface of the display device DD in the direction perpendicular to the thickness direction of the display device DD (i.e., in the second direction). A width (a maximum width in the second direction) D1 of the first sub-sealing material 92 may be greater than a width (a maximum width in the second direction) D2 of the second sub-sealing material 94.

The frame FR may surround the side surface of the display device DD and outer portions of a top surface of the upper structure US. The first sealing material 90 may be disposed between the side surface of the display device DD and the frame FR.

According to embodiments, a resin composition or a resin ink including the resin material may be coated on the side surface of the display panel DP to form a first preliminary sealing material. The resin composition may include the resin material and a curing agent. The curing agent may include a thermally curable agent and/or a photo-curable agent.

The first preliminary sealing material may cover (or overlap) a portion of the side surface of the display panel DP corresponding to the folding area FA, and may not be formed on the side surface of the lower support plate LSP including the lattice bar LB. Thereafter, the first preliminary sealing material may be cured to form the first sub-sealing material 92.

Thereafter, the resin composition may be coated on the upper surface of the first sub-sealing material 92 to form a second preliminary sealing material. The second sub-sealing material 94 may be formed by curing the second preliminary sealing material.

The second preliminary sealing material or the second sub-sealing material 94 may not be in contact with a lower surface of the first sub-sealing material 92 in the thickness direction of the display device DD (i.e., the third direction). The second preliminary sealing material or the second sub-sealing material 94 may be in at least partial contact with the side surface of the upper structure US of the folding area FA. In an embodiment, the second preliminary sealing material or the second sub-sealing material 94 may not contact the side surface of the display panel DP.

As described above, the first sub-sealing material 92 may be formed in advance, and then the resin composition may be applied to form the second preliminary sealing material. Accordingly, the first sub-sealing material 92 may function as a dam that may block resin composition components included in the second preliminary sealing material from flowing into the lower support plate LSP.

Accordingly, deterioration of flexibility and folding properties of the folding area FA by penetration and aggregation of the resin composition into the lattice bar LB and the opening OP may be prevented.

A coating area of the first preliminary sealing material may be limited above the lower support plate LSP to prevent penetration of the resin composition into the lattice bar LB and the opening OP when forming the first sub-sealing material 92.

According to embodiments, a coating amount (a weight) of the resin composition for forming the second preliminary sealing material may be less than a coating amount (a weight) of the resin composition for forming the first preliminary sealing material. Thus, penetration of the resin composition into the lattice bar LB and the opening OP may be more effectively prevented.

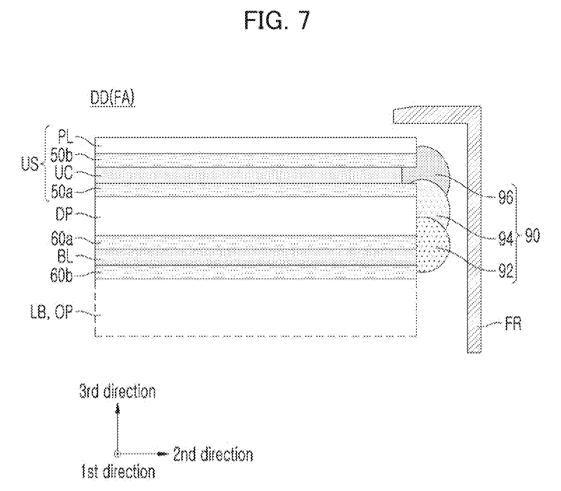

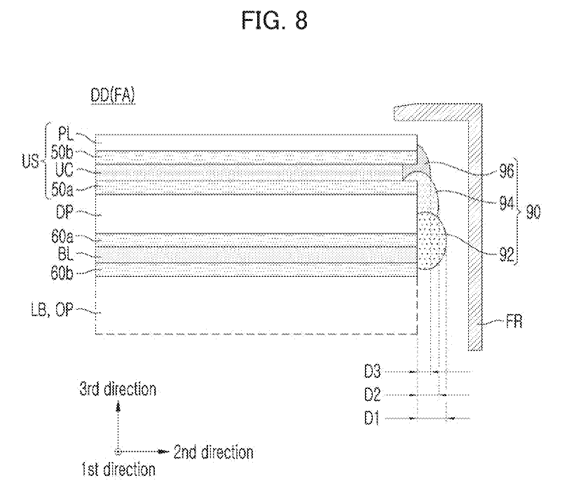

FIGS. 7 and 8 are schematic cross-sectional views illustrating a side portion of a folding area of a display device according to embodiments.

Referring to FIG. 7, the first sealing material 90 formed on a portion of the side surface of the display device DD corresponding to the folding area FA may include a first sub-sealing material 92, a second sub-sealing material 94, and a third sub-sealing material 96. The first sub-sealing material 92, the second sub-sealing material 94, and the third sub-sealing material 96 may be sequentially stacked in a direction from the lower structure LS to the upper structure US.

The first sub-sealing material 92 and the second sub-sealing material 94 may partially overlap each other, and the second sub-sealing material 94 and the third sub-sealing material 96 may partially overlap each other. The first sub-sealing material 92 and the third sub-sealing material 96 may be physically spaced apart from each other in the third direction with the second sub-sealing material 94 disposed therebetween.

According to embodiments, as described with reference to FIG. 6, a first preliminary sealing material may be formed using a resin composition, and then the first preliminary sealing material may be cured to form the first sub-sealing material 92. A second preliminary sealing material may be formed on an upper surface of the first sub-sealing material 92 using the resin composition, and then the second preliminary sealing material may be cured to form the second sub-sealing material 94. A third preliminary sealing material may be formed on an upper surface of the second sub-sealing material 94 using the resin composition, and then the third preliminary sub-sealing material may be cured to form the third sub-sealing material 96.

Referring to FIG. 8, a width D1 of the first sub-sealing material 92 may be greater than a width D2 of the second sub-sealing material 94. A width D2 of the second sub-sealing material 94 may be greater than a width D3 of the third sub-sealing material 96. The widths D1, D2, and D3 are taken in the second direction which is normal to the side surface of the display device.

According to embodiments, a coating amount of the resin composition for forming the third preliminary sealing material may be less than a coating amount of the resin composition for forming the second preliminary sealing material. The second sub-sealing material 94 may function as a dam that may block a flow of the resin composition included in the third preliminary sealing material.

Accordingly, the widths may sequentially decrease in order of the first sub-sealing material 92, the second sub-sealing material 94, and the third sub-sealing material 96.

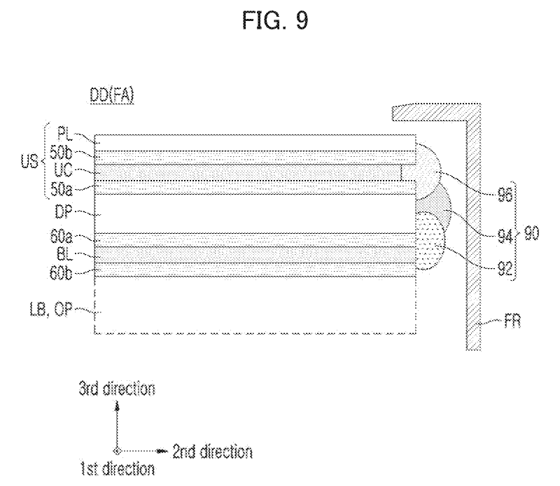

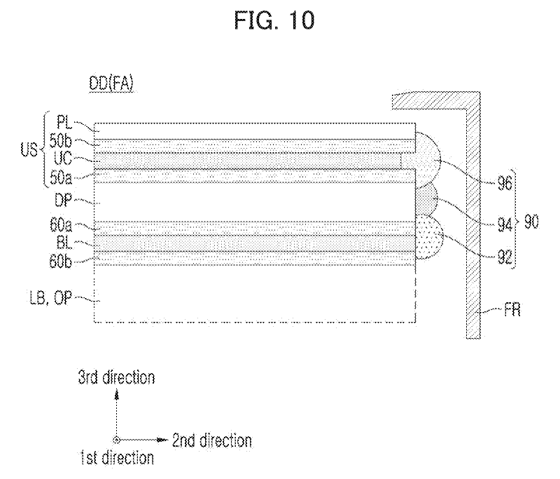

FIGS. 9 and 10 are schematic cross-sectional views illustrating a side portion of a folding area of a display device according to embodiments.

Referring to FIG. 9, the second sub-sealing material 94 may partially cover (or overlap) the first sub-sealing material 92 and the third sub-sealing material 96 in the direction perpendicular to the thickness direction of the display device DD (i.e., in the second direction).

According to embodiments, after forming the first sub-sealing material 92 and the third sub-sealing material 96, the second sub-sealing material 94 may be formed.

For example, the resin composition may be coated on each of a lower portion of the side surface and a portion of the upper side surface of the display device DD in the folding area FA, and then cured to form the first sub-sealing material 92 and the third sub-sealing material 96. The first sub-sealing material 92 and the third sub-sealing material 96 may be formed to be spaced apart from each other in the third direction.

Thereafter, the resin composition may be coated in a space between the first sub-sealing material 92 and the third sub-sealing material 96, and then cured to form the second sub-sealing material 94.

Referring to FIG. 10, a width in the second direction of the second sub-sealing material 94 may be less than each of a width the first sub-sealing material 92 and a width of the third sub-sealing material 96.

As described with reference to FIG. 9, the resin composition may be filled in a space between the first sub-sealing material 92 and the third sub-sealing material 96 to form a second preliminary sealing material, and then cured to form the second sub-sealing material 94.

According to embodiments, a coating amount of the resin composition for forming the second preliminary sealing material may be less than a coating amount of the resin composition for forming each of the first preliminary sealing material and the third preliminary sealing material.

Accordingly, an increase of a size of the first sealing material 90 due to the addition of the second sub-sealing material 94 may be prevented. Thus, a gap between the first sealing material 90 and the frame FR may be reduced.

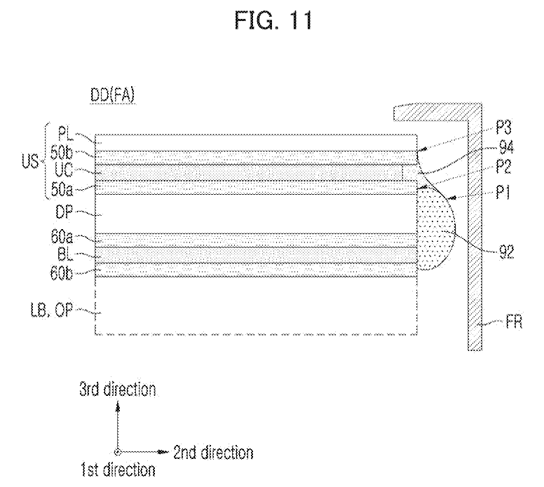

FIG. 11 is a schematic cross-sectional view illustrating a side portion of a folding area of a display device according to embodiments. To the extent that an element is not described in detail with respect to FIG. 11, it may be understood that the element is at least similar to a corresponding element that has been described previously with reference to FIG. 6.

Referring to FIG. 11, a width of the second sub-sealing material 94 may decrease along the side surface of the upper structure US from an upper portion of the first sub-sealing material 92. According to embodiments, the width of the second sub-sealing material 94 may gradually decrease from the upper portion of the first sub-sealing material 92.

In some embodiments, a virtual straight line connecting a lowermost point P1 of the second sub-sealing material 94 and an uppermost point P3 of the second sub-sealing material 94, and a virtual straight line connecting the lowermost point P1 of the second sub-sealing material 94 and a point P2 at which the second sub-sealing material 94, the first sub-sealing material 92 and the side surface (a side surface of the upper structure US) of the display device DD meet each other may form an intersection angle corresponding to an acute angle.

For example, the intersection angle may be in a range from about 5o to about 60o, from about 5o to about 50o, or from about 5o to about 40o.

For example, a coating amount of the resin composition for forming the second preliminary sealing material may be gradually reduced from the upper surface of the first sub-sealing material 92. Thus, a flow of the resin composition from the second preliminary sealing material may be more effectively suppressed.

According to the above-described embodiments of the disclosure, the first sealing material 90 formed on a portion of the side surface of the display device DD corresponding to the folding area FA may be divided into multiple sub-sealing materials. Accordingly, a coating amount of the resin composition for forming the first sealing material 90 may be reduced, and the resin composition may be prevented from penetrating into the surface and the opening OP of the lattice bars LB of the lower support plate LSP and aggregating therein.

Further, a size of the first sealing material 90 may be reduced, so that a space for arranging the frame FR may be reduced. Thus, an area of the active area AA and the display area DA may be increased while reducing a deco area and a bezel area of the display device DD.

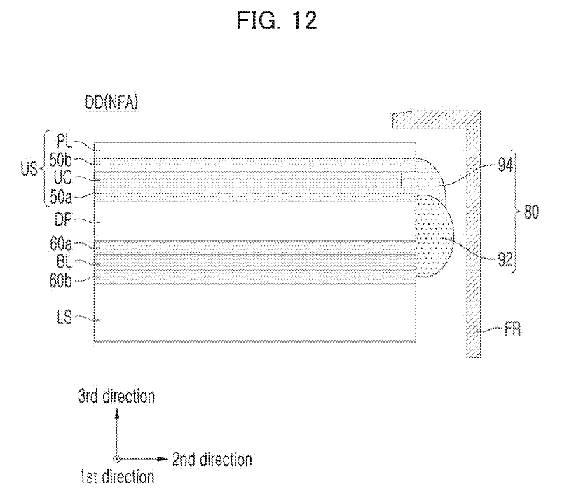

FIG. 12 is a schematic cross-sectional view illustrating a portion of a side portion corresponding to a non-folding area of a display device according to embodiments.

Referring to FIG. 12 and in the non-folding area NFA, a second sealing material 80 may be formed on a side surface of the display device DD. The second sealing material 80 in the non-folding area NFA and the first sealing material 90 in the folding area FA may include substantially a same resin material.

The second sealing material 80 may commonly share the first sub-sealing material 92 and the second sub-sealing material 94 included in the first sealing material 90. According to embodiments, the first sub-sealing material 92 and the second sub-sealing material 94 may extend continuously throughout the folding area FA and the non-folding area NFA, e.g., in the first direction.

For example, the resin composition may be continuously coated on the folding area FA and the non-folding area NFA, and then cured to form the first sub-sealing material 92. Thereafter, the resin composition may be continuously coated on the upper surface of the first sub-sealing material 92 throughout the folding area FA and the non-folding area NFA, and then cured to form the second sub-sealing material 94.

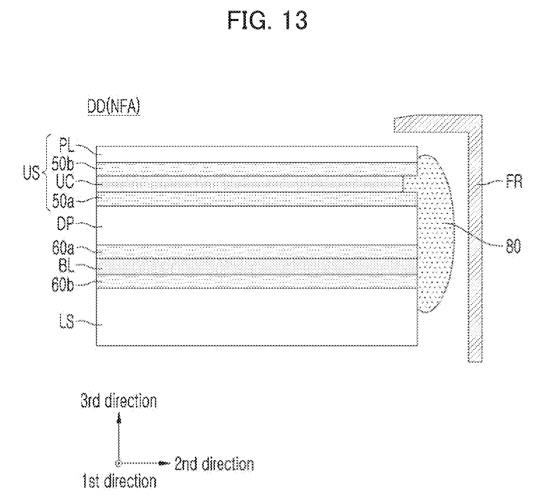

FIG. 13 is a schematic cross-sectional view illustrating a side portion of a non-folding area of a display device according to embodiments.

Referring to FIG. 13, the second sealing material 80 may be formed on the side surface of the display device DD in the non-folding area NFA as a single, uninterrupted member or a single layer.

The second sealing material 80 may cover the side surface of the display panel DP and the side surface of the upper structure US in the non-folding area NFA. In some embodiments, the second sealing material 80 may also cover the side surface of the lower structure LS of the non-folding area NFA. For example, the second sealing material 80 may partially cover the side surface of the lower structure LS of the non-folding area NFA. In an embodiment, the second sealing material 80 may at least partially cover a side surface of the lower support plate LSP of the non-folding area NFA.

As described above, the lattice bar LB and the opening OP may not be included in a portion of the lower support plate LSP of the non-folding area NFA. Accordingly, a length (a length in the third direction) of the second sealing material 80 may be additionally extended to the non-folding area NFA which may be free from penetration/aggregation of the resin composition, thereby enhancing stability with respect to impact and moisture permeation in the non-folding area NFA.

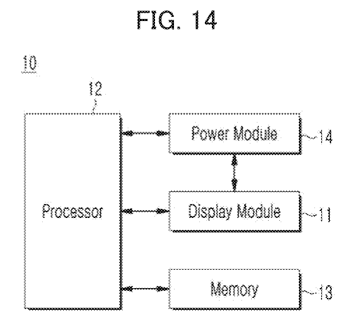

FIG. 14 is a block diagram of an electronic device according to an embodiment.

Referring to FIG. 14, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Some of individual modules functionally included in a module may be included in the display device, and others may be provided separately from the display device. For example, the display module 11 may include the display device, while the processor 12, the memory 13 and the power module 14 may be provided in the form of another device in the electronic device 10 different from the display device.

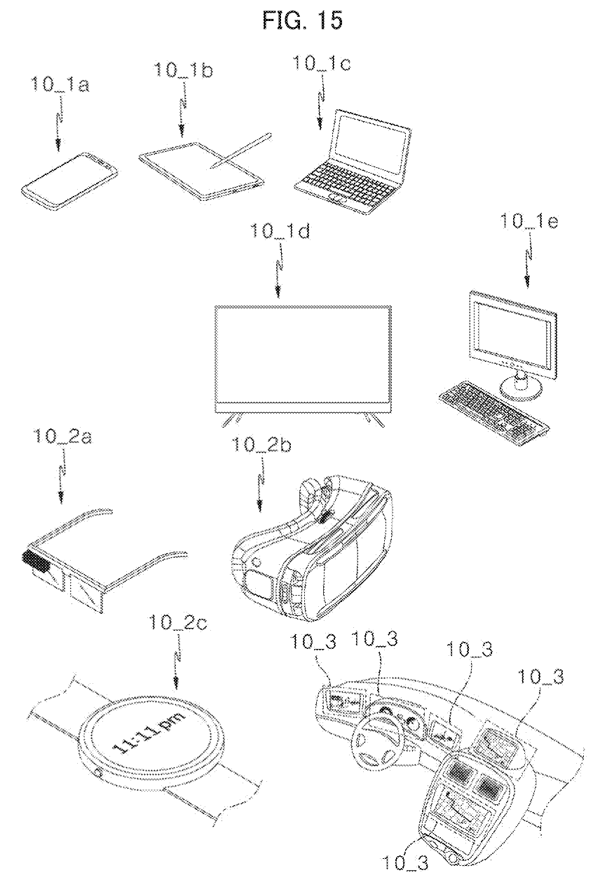

FIG. 15 is a schematic diagram of electronic devices according to embodiments.

Referring to FIG. 15, non-limiting examples of various electronic devices to which the display device according to the above-described embodiments is applied include an electronic device for displaying an image such as a smartphone 10_1a, a tablet 10_1b, a laptop 10_1c, a TV 10_1d, a monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (CID) disposed at a vehicle instrument panel, a center fascia, a dashboard, etc., a head-up display, a room mirror display, or the like. The electronic device may include virtual reality glasses or augmented reality glasses.

According to embodiments of the disclosure, there are provided a display device, an electronic device including the display device, and a method of manufacturing the display device, in which a multi-layer sealing structure is formed along side surfaces of a folding area to suppress resin penetration into a lower support structure, thereby improving mechanical reliability and reducing the area occupied by the sealing material and the bezel.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device, comprising:
a display panel having a folding area and a non-folding area;
an upper structure disposed on the display panel in a thickness direction of the display device, the upper structure including an upper cover;
a lower structure disposed under the display panel in the thickness direction of the display device, the lower structure including a lower support plate including lattice bars in an area overlapping the folding area; and
a first sealing material disposed on a portion of a side surface of the display panel corresponding to the folding area, the first sealing material comprising:
a first sub-sealing material disposed on the portion of the side surface of the display panel corresponding to the folding area; and
a second sub-sealing material disposed on an upper surface of the first sub-sealing material to partially overlap the first sub-sealing material in a direction perpendicular to the thickness direction.

2. The display device of claim 1, wherein the first sealing material does not cover a side surface of the lower support plate.

3. The display device of claim 1, wherein a width of the second sub-sealing material in the direction perpendicular to the thickness direction is less than a width of the first sub-sealing material in the direction perpendicular to the thickness direction.

4. The display device of claim 1, wherein the second sub-sealing material contacts a side surface of the upper structure and does not contact the side surface of the display panel.

5. The display device of claim 4, wherein the first sub-sealing material contacts an entirety of a portion of the side surface of the display panel corresponding to the folding area.

6. The display device of claim 1, wherein
the first sealing material further comprises a third sub-sealing material contacting an upper surface of the second sub-sealing material to partially overlap the second sub-sealing material in the direction perpendicular to the thickness direction, and
the third sub-sealing material and the first sub-sealing material are spaced apart from each other in the thickness direction.

7. The display device of claim 6, wherein
a width of the first sub-sealing material in the direction perpendicular to the thickness direction of the display device is greater than a width of the second sub-sealing material in the direction perpendicular to the thickness direction of the display device, and
the width of the second sub-sealing material in the direction perpendicular to the thickness direction is greater than a width of the third sub-sealing material in the direction perpendicular to the thickness direction.

8. The display device of claim 6, wherein the second sub-sealing material partially overlaps upper surfaces of the first sub-sealing material and the third sub-sealing material in the direction perpendicular to the thickness direction at locations between the first sub-sealing material and the third sub-sealing material.

9. The display device of claim 8, wherein a width of the second sub-sealing material in the direction perpendicular to the thickness direction is less than each of a width of the first sub-sealing material in the direction perpendicular to the thickness direction and a width of the third sub-sealing material in the direction perpendicular to the thickness direction .

10. The display device of claim 1, wherein the second sub-sealing material has a width in the direction perpendicular to the thickness direction that decreases in the thickness direction from the display panel to the upper structure.

11. The display device of claim 10, wherein a virtual straight line connecting a lowermost point and an uppermost point of the second sub-sealing material, and another virtual straight line connecting the lowermost point of the second sub-sealing material and a point where the second sub-sealing material, the first sub-sealing material and the side surface of the display device meet each other form an acute intersection angle.

12. The display device of claim 1, further comprising a second sealing material overlapping a portion of the side surface of the display panel corresponding to the non-folding area in the direction perpendicular to the thickness direction.

13. The display device of claim 12, wherein the second sealing material comprises:
the first sub-sealing material; and
the second sub-sealing material.

14. The display device of claim 12, wherein the second sealing material is a single sealing member.

15. The display device of claim 14, wherein the second sealing material overlaps a side surface of the lower support plate in the direction perpendicular to the thickness direction.

16. A method of manufacturing a display device, comprising:
preparing a display device including a lower support plate, a display panel and an upper cover that are sequentially stacked;
forming a first preliminary sealing material by coating a resin composition on a portion of a side surface of the display panel corresponding to a folding area of the display device;
curing the first preliminary sealing material to form a first sub-sealing material;
forming a second preliminary sealing material by coating the resin composition to partially overlap an upper surface of the first sub-sealing material in a direction perpendicular to a thickness direction of the display device; and
curing the second preliminary sealing material to form a second sub-sealing material.

17. The method of claim 16, wherein a coating amount of the resin composition for forming the second preliminary sealing material is less than a coating amount of the resin composition for forming the first preliminary sealing material.

18. The method of claim 16, wherein the first preliminary sealing material does not overlap in the direction perpendicular to the thickness direction a portion of a side surface of the lower support plate corresponding to the folding area.

19. An electronic device, comprising
a display device;
a memory; and
a processor executing data stored in the memory to control an operation of the display device, wherein the display device comprises:
a display panel having a folding area and a non-folding area;
an upper structure disposed on the display panel in a thickness direction of the display device, the upper structure including an upper cover;
a lower structure disposed under the display panel in the thickness direction of the display device, the lower structure including a lower support plate including lattice bars in an area overlapping the folding area; and
a first sealing material disposed on a portion of a side surface of the display panel corresponding to the folding area, the first sealing material comprising:
a first sub-sealing material disposed on the portion of the side surface of the display panel corresponding to the folding area; and
a second sub-sealing material disposed on an upper surface of the first sub-sealing material to partially overlap the first sub-sealing material in a direction perpendicular to the thickness direction.

20. The electronic device of claim 19, wherein the electronic device includes virtual reality or augmented reality glasses, a smartphone, a tablet, a laptop, a TV, a monitor, smart glasses, a head-mounted display, a smart watch, or a vehicle display.
